(19) United States
(12) Patent Application Publication
(10) Pub. No.: US 2026/0206127 A1
(43) Pub. Date: Jul. 16, 2026

(54) WIRING BOARD, ELECTRONIC-COMPONENT-MOUNTING PACKAGE USING WIRING BOARD, AND ELECTRONIC MODULE

(71) Applicant: KYOCERA Corporation, Kyoto-shi, Kyoto (JP)

(72) Inventor: Yoshiki KAWAZU, Omihachiman-shi, Shiga (JP)

(73) Assignee: KYOCERA Corporation, Kyoto-shi, Kyoto (JP)

(21) Appl. No.: 19/136,452

(22) PCT Filed: Dec. 6, 2023
(86) PCT No.: PCT/JP2023/043635

§ 371 Date: Jun. 6, 2025

(30) Foreign Application Priority Data
Dec. 7, 2022 (JP) 2022-195727

(51) Int. Cl. H05K 1/02

(52) U.S. Cl. CPC H05K 1/0216; H05K 2201/09227

(57) ABSTRACT

A wiring board includes: an insulator; and a first ground conductor, a first signal conductor, a second signal conductor, and a second ground conductor arranged in this order in a first direction on the insulator. The insulator includes a first region extending in the first direction and a first opening part positioned in the first region. The first ground conductor includes a first ground line and a second ground line opposite to each other. The second ground conductor includes a third ground line and a fourth ground line opposite to each other. The first signal conductor includes: a pair of first electrode portions opposite to each other across the first region; a first line portion; and a second line portion. The second signal conductor includes: a pair of second electrode portions opposite to each other across the first region; a third line portion; and a fourth line portion. The first opening part is positioned in a first portion, of the first region, positioned between the first signal conductor and the second signal conductor in the first direction.

### TECHNICAL FIELD

The present disclosure relates to a wiring board, an electronic-component-mounting package using a wiring board, and an electronic module.

### BACKGROUND OF INVENTION

For example, Patent Literature 1 describes a wiring board of a known technique.

### CITATION LIST

### Patent Literature

Patent Literature 1: International Publication No. 2020/040072

### SUMMARY

In an embodiment, a wiring board includes an insulator, a ground conductor part, and a signal conductor part. The insulator includes a first upper surface. The first upper surface includes a first region extending in a first direction. The ground conductor part is positioned on the first upper surface and extends in a second direction crossing the first direction. The signal conductor part is positioned on the first upper surface and extends in the second direction. The insulator includes a first opening part including at least a portion positioned in the first region. The ground conductor part includes a first ground conductor, and a second ground conductor spaced from the first ground conductor. The signal conductor part includes a first signal conductor and a second signal conductor. The first signal conductor is positioned between the first ground conductor and the second ground conductor. The second signal conductor is spaced from the first signal conductor and positioned between the first ground conductor and the second ground conductor. The first ground conductor includes a first ground line and a second ground line. The second ground line is opposite to the first ground line across the first region in the second direction. The second ground conductor includes a third ground line and a fourth ground line. The fourth ground line is opposite to the third ground line across the first region in the second direction. The first signal conductor includes a pair of first electrode portions, a first line portion, and a second line portion. The pair of first electrode portions are opposite to each other across the first region in the second direction. The first line portion is connected to one of the pair of first electrode portions and extends away from the first region. The second line portion is connected to the other of the pair of first electrode portions and extends away from the first region. The second signal conductor includes a pair of second electrode portions, a third line portion, and a fourth line portion. The pair of second electrode portions are opposite to each other across the first region in the second direction. The third line portion is connected to one of the pair of second electrode portions and extends away from the first region. The fourth line portion is connected to the other of the pair of second electrode portions and extends away from the first region. The first ground conductor, the first signal conductor, the second signal conductor, and the second ground conductor are arranged in this order in the first direction in plan view. The first opening part is positioned in a first portion, of the first region, positioned between the first signal conductor and the second signal conductor in the first direction.

In an embodiment, an electronic-component-mounting package includes the wiring board, a substrate, and a frame body. The frame body is positioned on the substrate. The wiring board is fixed to the frame body.

In an embodiment, an electronic module includes the electronic-component-mounting package, an electronic component, and a lid body. The electronic component is accommodated in the electronic-component-mounting package and electrically connected to the wiring board. The lid body is bonded on the frame body and covers an inside of the electronic-component-mounting package.

### BRIEF DESCRIPTION OF THE DRAWINGS

FIG. 1 is a perspective view of a wiring board according to a first embodiment.

FIG. 2 is a plan view of the wiring board according to the first embodiment.

FIG. 3 is a perspective view of the wiring board, according to the first embodiment, on which a capacitor is mounted.

FIG. 4 is a perspective view of a wiring board according to a second embodiment.

FIG. 5 is a plan view of the wiring board according to the second embodiment.

FIG. 6 is a perspective view of a wiring board according to a third embodiment.

FIG. 7 is a plan view of the wiring board according to the third embodiment.

FIG. 8 is a perspective view of a wiring board according to a fourth embodiment.

FIG. 9 is a plan view of the wiring board according to the fourth embodiment.

FIG. 10 is a perspective view of a wiring board according to a fifth embodiment.

FIG. 11 is a plan view of the wiring board according to the fifth embodiment.

FIG. 12 is a sectional view of the wiring board illustrated in FIG. 11, taken along line XII-XII.

FIG. 13 is an exploded perspective view of the wiring board according to the fifth embodiment.

FIG. 14 is a perspective view of a wiring board according to a sixth embodiment.

FIG. 15 is a plan view of the wiring board according to the sixth embodiment.

FIG. 16 is an enlarged perspective view of related part A in FIG. 14.

FIG. 17 is an exploded perspective view of an electronic-component-mounting package including the wiring board according to an embodiment and an electronic module.

FIG. 18 is a graph illustrating reflection characteristics of the wiring boards according to the fourth embodiment and the fifth embodiment.

FIG. 19 is a graph illustrating bandpass characteristics of the wiring boards according to the fourth embodiment and the fifth embodiment.

FIG. 20 is a graph illustrating TDR (time domain reflectometry) of the wiring boards according to the fourth embodiment and the fifth embodiment.

### DESCRIPTION OF EMBODIMENTS

In the technique disclosed in Patent Literature 1, the wiring board includes, on a ceramic base body, a first ground pattern, a first wiring path, a second wiring path, a second ground pattern, a first pad pair, and a second pad pair. The first pad pair is provided in the middle of the first wiring path. The second pad pair is provided in the middle of the second wiring path. In the technique disclosed in Patent Literature 1, the wiring board in which a capacitor is mounted on each of the first pad pair and the second pad pair is described.

However, when a capacitor in which reduction in size and height has progressed is mounted on each of the first pad pair and the second pad pair by a bonding material such as solder, the bonding material may be connected across the first pad pair and/or across the second pad pair. Thus, the first pad pair and/or the second pad pair may be electrically short-circuited by being electrically connected between the pair.

When reduction in size and height of a wiring board further progresses, the first ground pattern and/or the second ground pattern is required to be brought close to a corresponding one of the first wiring path and the second wiring path. In such a case, the bonding material may be electrically short-circuited by coming into contact with the first ground pattern and/or the second ground pattern. The adjustment of impedance values in the first wiring path and the second wiring path may become difficult.

### Configuration of Wiring Board

Hereinafter, exemplary embodiments will be described with reference to the drawings. Note that, in a wiring board, any direction may be upward or downward, but, while the rectangular coordinate system xyz is defined, the positive side in a z direction is referred to as the upward side for convenience. In the present disclosure, “in plan view” is a concept that includes “in plan perspective”. In the present disclosure, a first direction refers to, for example, an x direction in the drawings. A second direction refers to, for example, a y direction in the drawings. A third direction refers to, for example, the z direction in the drawings. Note that, in the present disclosure, a width, a length, and a thickness can refer to a dimension in the x direction, a dimension in the y direction, and a dimension in the z direction, respectively.

Hereinafter, in the constituents of a second embodiment, a third embodiment, a fourth embodiment, a fifth embodiment, and a sixth embodiment, only differences in constituents between the embodiments will be described, and the description of the other constituents will be omitted while corresponding constituents in the respective embodiments are denoted by the same reference sign.

### First Embodiment

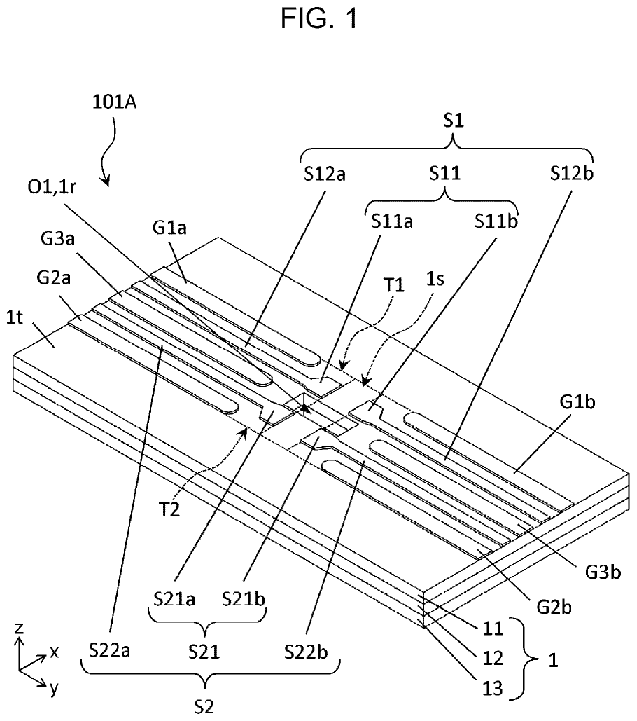

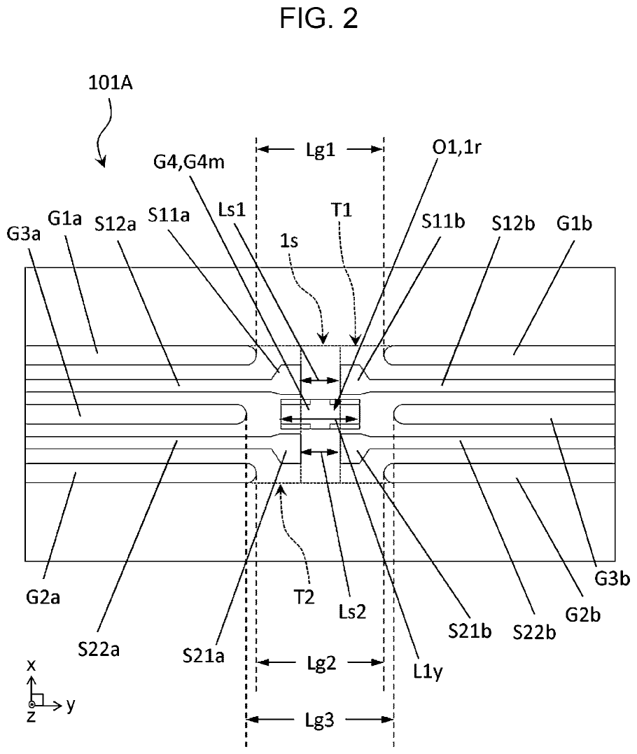

A wiring board 101A according to a first embodiment will be described with reference to FIGS. 1 to 3. Note that, in some of the drawings, a first region 1s is omitted for convenience.

The wiring board 101A includes an insulator 1, a ground conductor part G0, and a signal conductor part S0.

The insulator 1 includes a first upper surface It. The first upper surface It includes the first region is extending in the first direction (in other words, the x direction). The first region is may be defined as a region interposed between a pair of first electrode portions S11 and a pair of second electrode portions 521, which will be described later. More specifically, the first region is may extend, in the x direction, at least from a first imaginary line T1 connecting an outer edge of a first ground line G1a and an outer edge of a second ground line G1b to a second imaginary line T2 connecting an outer edge of a third ground line G2a and an outer edge of a fourth ground line G2b. The first region is has a rectangular shape in an embodiment but may have an oval shape. The first region is may be partially inclined in the y direction.

For the material of the insulator 1, for example, a ceramic material such as sintered aluminum oxide, sintered mullite, sintered silicon carbide, sintered aluminum nitride, or sintered silicon nitride, or a dielectric material such as a glass ceramic material or a glass epoxy material can be used.

The insulator 1 may be a single layer or may be a configuration in which multiple insulating layers are stacked. For example, the insulator 1 has a rectangular shape in plan view and has a size of from 4 mm×4 mm to 50 mm×50 mm and a thickness of from 0.5 mm to 10 mm. In an embodiment, as illustrated in FIG. 1 and the like, the insulator 1 may be a configuration in which a third insulating layer 13, a second insulating layer 12, and a first insulating layer 11 are stacked in this order in a positive direction of the z axis.

The insulator 1, and the ground conductor part G0 and the signal conductor part S0, which will be described later, may be made by AM (additive manufacturing) using a 3D printer.

The insulator 1 can be manufactured as follows, for example. Multiple green sheets are processed by using a mold and/or the like, and the multiple green sheets each formed into an outside shape of the insulator 1 are prepared. Then, the multiple green sheets are stacked, with outer edge portions thereof coinciding with one another, into a green sheet multilayer body. The multiple green sheets are sintered by firing the green sheet multilayer body, and the insulator 1 can be obtained. The ground conductor part G0 is positioned on the first upper surface It and extends in the second direction (in other words, the y direction) crossing the first direction. The ground conductor part G0 includes a first ground conductor G1 and a second ground conductor G2. The second ground conductor G2 is spaced from the first ground conductor G1.

Examples of the material of the ground conductor part G0 include metal materials such as gold, silver, copper, nickel, tungsten, molybdenum, and manganese. The ground conductor part G0 may be formed by sintering a metal paste on the first upper surface It or may be formed by using a thin film forming technique such as a vapor deposition method or a sputtering method. For the first ground conductor G1, the second ground conductor G2, and a third ground conductor G3, which will be described later, the same material is not necessarily used, and different materials may be used.

A metal plating such as a nickel plating or a gold plating may be formed on a surface of the ground conductor part G0. An insulating film of a ceramic (such as an alumina coat), a resin, and/or the like may further be positioned on a portion of the ground conductor part G0. The insulating film can be formed on the ground conductor part G0 by screen printing. The insulating film may be positioned only on a portion of the ground conductor part G0. Such a configuration can reduce the possibility of a short circuit between the ground conductor part G0 and any other wire.

The first ground conductor G1 includes the first ground line G1a and the second ground line G1b. The second ground line G1b is opposite to the first ground line G1a across the first region is in the y direction. That is, the first ground line G1a and the second ground line G1b are separated from each other by the first region is. Such a state may translate into a state where the first ground conductor G1 is cut by the first region 1s. Each of the first ground line G1a and the second ground line G1b has a straight-line shape in an embodiment but may have a partially curved shape. The first ground line G1a and the second ground line G1b have shapes line symmetric across the first region is in an embodiment but may have different shapes.

The first ground conductor G1 may be electrically connected to an inner-layer ground conductor G4 by a via and/or the like. More specifically, the first ground line G1a and the second ground line G1b may each be electrically connected to the inner-layer ground conductor G4 by a via and/or the like. In this case, the first ground line G1a and the second ground line G1b may be electrically connected to each other with the inner-layer ground conductor G4 therebetween. The third ground line G2a and the fourth ground line G2b, which will be described later, can have the same or similar configuration to the configuration of the first ground line G1a and the second ground line G1b.

The second ground conductor G2 includes the third ground line G2a and the fourth ground line G2b.

The fourth ground line G2b is opposite to the third ground line G2a across the first region is in the y direction. That is, the third ground line G2a and the fourth ground line G2b are separated from each other by the first region is. Such a state may translate into a state where the second ground conductor G2 is cut by the first region is. Each of the third ground line G2a and the fourth ground line G2b has a straight-line shape in an embodiment but may have a partially curved shape. The third ground line G2a and the fourth ground line G2b have shapes line symmetric across the first region is but may have different shapes. The second ground conductor G2 does not necessarily have the same shape as the first ground conductor G1 and may have a different shape. The first ground conductor G1 may have a width, a length, and a thickness that are the same as or different from the width, the length, and the thickness of the second ground conductor G2.

The signal conductor part S0 is positioned on the first upper surface It and extends in the y direction. The material of the signal conductor part S0 may be the same as or different from the material of the ground conductor part G0, and examples thereof include the same or similar materials to those of the ground conductor part G0 described above. Note that, for the signal conductor part S0 and the ground conductor part G0, the same and/or similar material is not necessarily used, and different materials may be used. The signal conductor part S0 may be formed by the same or similar method to the method for forming the ground conductor part G0 described above.

The signal conductor part S0 includes a first signal conductor S1 and a second signal conductor S2. In an embodiment, the first signal conductor S1 and the second signal conductor S2 form a pair of differential signal lines. Such differential signal lines can reduce the possibility of being affected by noise, compared with a single-end signal line.

The first signal conductor S1 is positioned between the first ground conductor G1 and the second ground conductor G2. The first signal conductor S1 includes the pair of first electrode portions S11, a first line portion S12a, and a second line portion S12b. The pair of first electrode portions S11 are opposite to each other across the first region is in the y direction. The first line portion S12a, while being connected to a first electrode portion S11a that is one of the pair of first electrode portions S11, extends away from the first region 1s. The second line portion S12b, while being connected to a first electrode portion S11b that is the other of the pair of first electrode portions S11, extends away from the first region is.

The first electrode portion S11a, which is one of the pair of first electrode portions S11, and the first electrode portion S11b, which is the other of the pair of first electrode portions S11, do not necessarily have shapes line symmetric across the first region 1s. That is, the pair of first electrode portions S11 may have the same shape or may have different shapes. In an embodiment, the width of the pair of first electrode portions S11 may be greater than each of the width of the first line portion S12a and the width of the second line portion S12b. Note that the width of the pair of first electrode portions S11 may be the same as or different from the width of each of the first line portion S12a and the second line portion S12b. The same configuration may be applied to the relationship between the width of the pair of second electrode portions S21, the width of a third line portion S22a, and the width of a fourth line portion S22b, which will be described later.

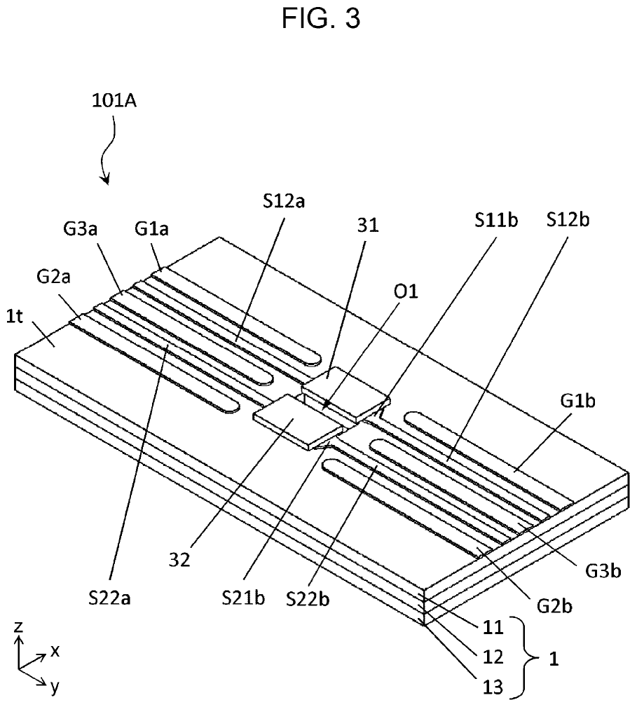

An electric circuit element, examples of which include a capacitor, an inductor, a resistor, a noise removal filter, and a chip bead, can be connected to the pair of first electrode portions S11. Note that, in an embodiment, a first capacitor 31 can be electrically connected to the pair of first electrode portions S11 as FIG. 3 illustrates. Such connection of the first capacitor 31 to the pair of first electrode portions S11 can reduce a direct-current voltage component of a signal that is transmitted through the first signal conductor S1.

The first capacitor 31 may have a rectangular shape in plan view and may have a size of from 0.1 mm×0.1 mm to 2 mm×4 mm and a height of from 0.1 mm to 3 mm. The width of the first capacitor 31 may be greater than the width of the pair of first electrode portions S11 in plan view. Examples of an ingredient of the first capacitor 31 include forsterite, aluminum oxide, barium magnesium niobate, and barium neodymium titanate. More specifically, the first capacitor 31 may be an MLCC (multi-layer ceramic capacitor) or may be a silicon capacitor.

The second signal conductor S2 is spaced from the first signal conductor S1 and positioned between the first ground conductor G1 and the second ground conductor G2. The second signal conductor S2 includes the pair of second electrode portions S21, the third line portion S22a, and the fourth line portion S22b. The pair of second electrode portions S21 are opposite to each other across the first region is in the y direction. The third line portion S22a, while being connected to a second electrode portion S21a that is one of the pair of second electrode portions 521, extends away from the first region is. The fourth line portion S22b, while being connected to a first electrode portion S21b that is the other of the pair of second electrode portions 521, extends away from the first region is.

An electric circuit element, examples of which include a capacitor, an inductor, and a resistor, can be connected to the pair of second electrode portions 521. Such an electric circuit element connected to the pair of second electrode portions S21 may be the same as or different from the electric circuit element connected to the pair of first electrode portions S11. Note that, in an embodiment, a second capacitor 32 can be electrically connected to the pair of second electrode portions S21 as FIG. 3 illustrates. Such connection of the second capacitor 32 to the pair of second electrode portions S21 can reduce a direct-current voltage component of a signal that is transmitted through the second signal conductor S2.

Note that, hereinafter, the pair of first electrode portions S11 and the pair of second electrode portions S21 are sometimes collectively referred to as an electrode portion. The first capacitor 31 and the second capacitor 32 are sometimes collectively referred to as an electric circuit element.

The first capacitor 31 can be connected to the pair of first electrode portions S11 by a bonding material. The second capacitor 32 can be connected to the pair of second electrode portions S21 by a bonding material. For such a bonding material is, for example, known solder such as Sn—Ag—Cu solder, Sn—Zn—Bi solder, or Sn—Cu solder can be used.

In plan view, the first ground conductor G1, the first signal conductor S1, the second signal conductor S2, and the second ground conductor G2 are arranged in this order in the x direction. In other words, the first signal conductor S1 and the second signal conductor S2 are interposed between the first ground conductor G1 and the second groundconductor G2 in the x direction. Thus, the wiring board 101A can be differential signal line or coplanar structure, thereby being able to stably transmit a radio-frequency signal in the signal conductor part S0.

The insulator 1 includes a first opening part O1. The first opening part O1 includes at least a portion positioned in the first region 1s. The first opening part O1 may be formed by subjecting punching to the insulator 1 before sintering or may be formed by subjecting a known hole forming process, examples of which include drilling, blasting, and laser processing, to the insulator 1 after sintering. The first opening part O1 has a rectangular shape including a round corner portion in plan view in an embodiment but may have a quadrilateral shape or a circular shape, examples of which include an oval shape, in plan view. The first opening part O1 may extend through the insulator 1.

The first opening part O1 is filled with at least one of dielectric materials such as air, a resin material, and a glass material and has a permittivity lower than the insulator 1. Thus, the characteristic impedance when a radio-frequency signal is transmitted can be adjusted to a desired value in the first signal conductor S1 and the second signal conductor S2. Thus, a signal power loss generated in the first signal conductor S1 and the second signal conductor S2 can be reduced.

The first opening part O1 is positioned in a first portion 1r of the first region 1s. The first portion 1r is positioned between the first signal conductor S1 and the second signal conductor S2 in the x direction. Thus, even when at least one of the amount of the bonding material connecting the first capacitor 31 to the pair of first electrode portions S11 and the amount of the bonding material connecting the second capacitor 32 to the pair of second electrode portions S21 is increased, the first opening part O1 can hold thereinside an excess bonding material, thereby being able to reduce the possibility of an electrical short circuit caused by inter-bonding material contact. An interval between the pair of first electrode portions S11 and the pair of second electrode portions S21 can be reduced accordingly. Thus, the electric circuit element can be stably mounted on the electrode portion even when the electric circuit element, with the wiring board 101A, is reduced in size.

In plan view, at least a portion of the inner-layer ground conductor G4 may be positioned in a bottom surface of the first opening part O1. That is, at least a portion of the inner-layer ground conductor G4 may be exposed at the bottom surface of the first opening part O1.

In an embodiment, a distance Ls1 between the pair of first electrode portions S11 in the y direction and a distance Ls2 between the pair of second electrode portions S21 in the y direction may each be less than at least one of a distance Lg1 between the first ground line G1a and the second ground line G1b in the y direction and a distance Lg2 between the third ground line G2a and the fourth ground line G2b in the y direction. More specifically, the first ground conductor G1 and the second ground conductor G2 are not necessarily positioned at least in a portion of a lateral region of the pair of first electrode portions S11 and a portion of a lateral region of the second electrode portions S21 in the x direction. An impedance value is likely to be low in the pair of first electrode portions S11 to which the first capacitor 31 is connected and in the pair of second electrode portions S21 to which the second capacitor 32 is connected. Thus, the above-described configuration can reduce the possibility of decrease in impedance value in the electrode portion. When the electric circuit element is mounted on the electrode portion, the above-described configuration can reduce the possibility of a short circuit of the first signal conductor S1 and/or the second signal conductor S2 caused by the bonding material, squeezed out when the electric circuit element is mounted on the electrode portion, being in contact with the first ground conductor G1 and/or the second ground conductor G2.

A dimension L1y of the first opening part O1 in the y direction may be greater than at least one of the distance Ls1 between the pair of first electrode portions S11 in the y direction and the distance Ls2 between the pair of second electrode portions S21 in the y direction. Thus, when the electric circuit element is mounted, the possibility of decrease in impedance value can be reduced in the electrode portion where an impedance value is likely to be low. Note that the dimension L1y of the first opening part O1 in the y direction refers to a maximum dimension of the first opening part O1 in the y direction.

Although the first line portion S12a, the second line portion S12b, the third line portion S22a, and the fourth line portion S22b are not positioned in any lateral region of the first opening part O1 in the x direction in an embodiment, at least one selected from the group consisting of the first line portion S12a, the second line portion S12b, the third line portion S22a, and the fourth line portion S22b may be positioned in a lateral region of the first opening part O1 in the x direction.

The dimension L1y of the first opening part O1 in the y direction may be less than at least one of the distance Lg1 between the first ground line G1a and the second ground line G1b in the y direction and the distance Lg2 between the third ground line G2a and the fourth ground line G2b in the y direction. That is, the first ground line G1a and the second ground line G1b may be away from each other in the y direction by a distance greater than the dimension L1y of the first opening part O1 in the y direction. The third ground line G2a and the fourth ground line G2b may be away from each other in the y direction by a distance greater than the dimension L1y of the first opening part O1 in the y direction. This configuration can keep the first ground conductor G1 and/or the second ground conductor G2 further away from the lateral region of the pair of first electrode portions S11 and from the lateral region of the pair of second electrode portions S21 in the x direction, thereby being able to reduce the possibility of decrease in impedance value in the electrode portion.

The ground conductor part G0 may further include the third ground conductor G3 positioned between the first signal conductor S1 and the second signal conductor S2. That is, the third ground conductor G3 may be interposed between the first signal conductor S1 and the second signal conductor S2.

The third ground conductor G3 may include a fifth ground line G3a and a sixth ground line G3b. Each of the fifth ground line G3a and the sixth ground line G3b has a straight-line shape in an embodiment but may have a partially curved shape.

The sixth ground line G3b may be opposite to the fifth ground line G3a across the first region is in the y direction. Such a configuration can strengthen the ground potential in the vicinity of the signal conductor part S0. Thus, the possibility of occurrence of resonance can be reduced in the first signal conductor S1 and the second signal conductor S2.

A distance Lg3 between the fifth ground line G3a and the sixth ground line G3b in the y direction may be greater than at least one of the distance Lg1 between the first ground line G1a and the second ground line G1b in the y direction and the distance Lg2 between the third ground line G2a and the fourth ground line G2b in the y direction. In a space interposed between the first signal conductor S1 and the second signal conductor S2 (in particular, the pair of first electrode portions S11 and the pair of second electrode portions S21), an impedance value is likely to decrease, but the above-described configuration can reduce the possibility of decrease in impedance value in the first signal conductor S1 and the second signal conductor S2.

### Second Embodiment

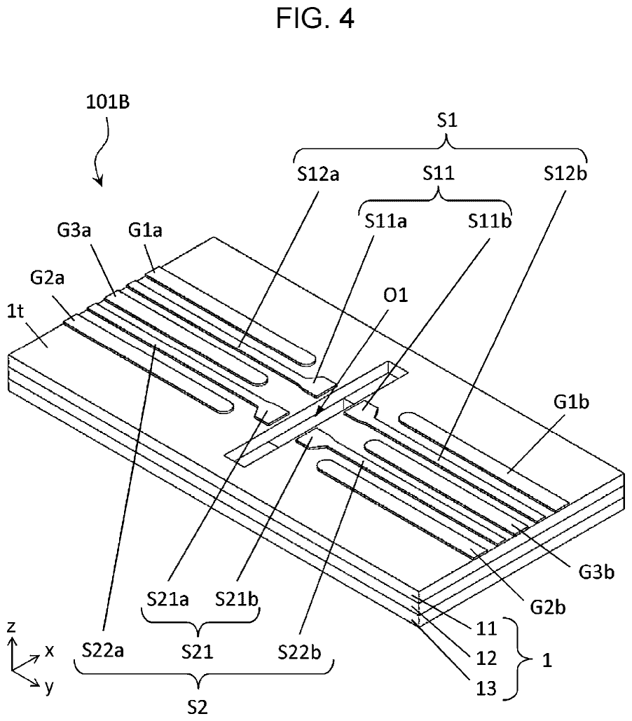

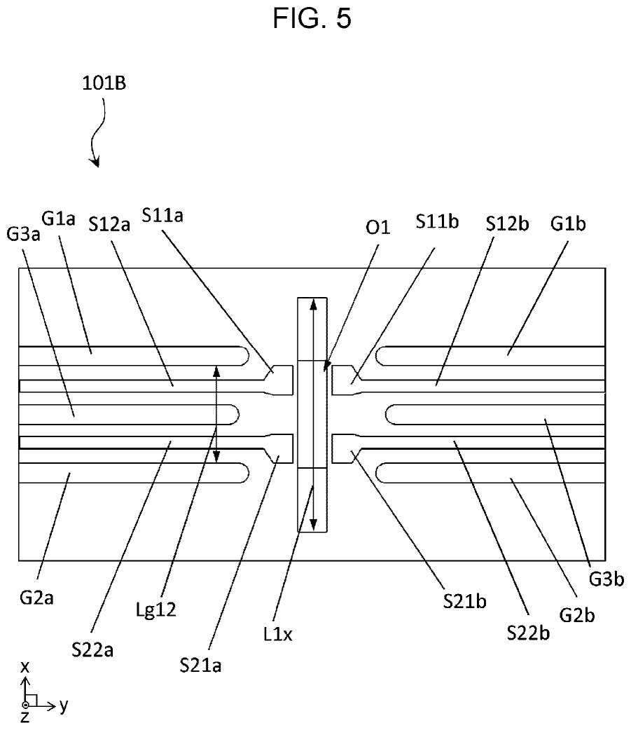

A wiring board 101B according to the second embodiment will be described with reference to FIGS. 4 and 5.

In the second embodiment, a first opening part O1 may extend at least from a spot between a pair of first electrode portions S11 to a spot between a pair of second electrode portions S21. That is, the first opening part O1 may be positioned below the first capacitor 31 and the second capacitor 32. Thus, even when at least one of the amount of the bonding material connecting the pair of first electrode portions S11 to the first capacitor 31 and the amount of the bonding material connecting the pair of second electrode portions S21 to the second capacitor 32 is increased, the first opening part O1 can hold thereinside an excess bonding material, thereby being able to reduce the possibility of an electrical short circuit caused by inter-bonding material contact. An interval between the pair of first electrode portions S11 and the pair of second electrode portions S21 can be reduced accordingly. Thus, the electric circuit element can be stably mounted on the electrode portion even when the electric circuit element, with the wiring board 101B, is reduced in size.

Here, the depth of a portion of the first opening part O1 may be shallow. That is, in a sectional view perpendicular to a first upper surface It, the first opening part O1 may include a level difference portion. Note that such a “depth” here can refer to a maximum dimension from the first upper surface It to a bottom surface of the first opening part O1 in the z direction. In a sectional view perpendicular to the first upper surface It, the bottom surface of the first opening part O1 may have a curved-line shape protruding in a negative direction of the z axis.

Note that, in an embodiment, in the x direction, the first opening part O1 may include a portion extending further in a positive direction of the x axis than a spot between the pair of first electrode portions S11. This portion may be considered as a second opening part O2, which will be described later.

In an embodiment, in the x direction, the first opening part O1 may include a portion extending further in a negative direction of the x axis than a spot between the pair of second electrode portions 521. This portion may be considered as a third opening part O3, which will be described later.

A dimension L1x of the first opening part O1 in the x direction may be greater than a distance Lg12 between a first ground conductor G1 and a second ground conductor G2 in the x direction. Such a “distance Lg12” between the first ground conductor G1 and the second ground conductor G2 in the x direction refers to a minimum distance of distances between an outer edge of the first ground conductor G1 and an outer edge of the second ground conductor G2. The first opening part O1 extends across the pair of first electrode portions S11, the pair of second electrode portions S21, the first ground conductor G1, and the second ground conductor G2 in the x direction, thereby being able to reduce the possibility of decrease in impedance value in the vicinity of the electric circuit element.

### Third Embodiment

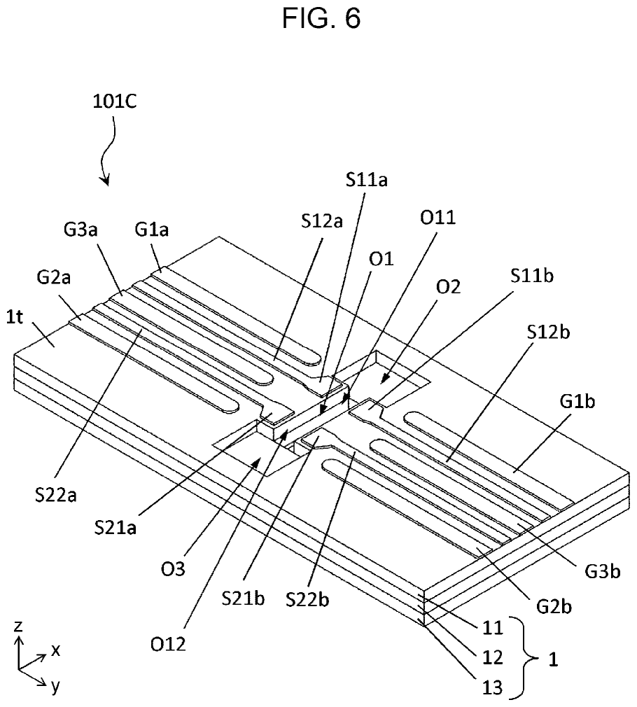

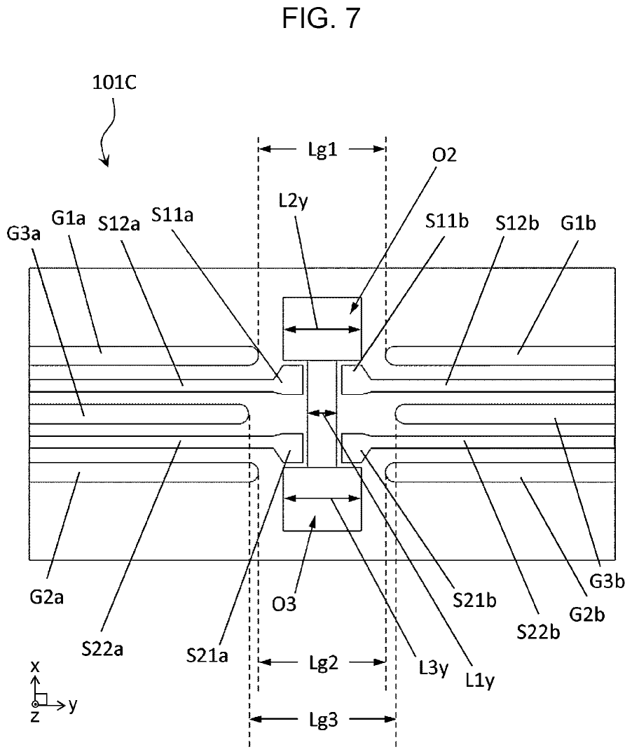

A wiring board 101C according to the third embodiment will be described with reference to FIGS. 6 and 7.

An insulator 1 may further include a second opening part O2 and a third opening part O3. The second opening part O2 and the third opening part O3 may be formed in the insulator 1 by the same or similar method to the method for forming the first opening part O1. Hereinafter, the first opening part O1, the second opening part O2, and the third opening part O3 are sometimes collectively referred to as an opening part.

At least a portion of the second opening part O2 may be positioned in a first region 1s. The second opening part O2 is positioned between a first ground line G1a and a second ground line G1b in the y direction and is spaced from a first signal conductor S1 in the x direction. In other words, the second opening part O2 is interposed between the first ground line G1a and the second ground line G1b in the y direction. The second opening part O2 is connected to the first opening part O1 in FIG. 6 but may be spaced from the first opening part O1. That is, the second opening part O2 and the first opening part O1 are not necessarily connected to each other.

At least a portion of the third opening part O3 may be positioned in the first region is. The third opening part O3 is positioned between a third ground line G2a and a fourth ground line G2b in the y direction and is spaced from a second signal conductor S2 in the x direction. In other words, the second opening part O2 is interposed between the third ground line G2a and the fourth ground line G2b in the y direction. The third opening part O3 is connected to the first opening part O1 in FIG. 6 but may be spaced from the first opening part O1. That is, the third opening part O3 and the first opening part O1 are not necessarily connected to each other.

With such an above-described configuration, at least a portion of a pair of first electrode portions S11 is surrounded by the first opening part O1 and the second opening part O2, and at least a portion of a pair of second electrode portions S21 is surrounded by the first opening part O1 and the third opening part O3. Thus, when the electric circuit element is mounted, the possibility of decrease in impedance value can be reduced more effectively in the electrode portion where an impedance value may be low.

With such an above-described configuration, the second opening part O2 and/or the third opening part O3 can hold thereinside an excess bonding material generated when the electric circuit element is mounted on the electrode portion. Thus, the possibility of inter-bonding material contact and/or the possibility of an electrical short circuit between the signal conductor part S0 and the ground conductor part G0 caused by the bonding material can be reduced.

As FIG. 6 illustrates, the first opening part O1 may include a first connection portion O11 and a second connection portion O12.

The first connection portion O11 may be connected to the second opening part O2. The first connection portion O11 is positioned between the pair of first electrode portions S11 in the y direction. That is, in the first opening part O1, a region that is positioned between the pair of first electrode portions S11 in the y direction and in which the first opening part O1 and the second opening part O2 are connected to each other can serve as the first connection portion O11.

The second connection portion O12 may be connected to the third opening part O3. The second connection portion O12 is positioned between the pair of second electrode portions S21 in the y direction. That is, in the first opening part O1, a region that is positioned between the pair of second electrode portions S21 in the y direction and in which the first opening part O1 and the third opening part O3 are connected to each other can serve as the second connection portion O12.

Such an above-described configuration can effectively reduce the possibility of decrease in impedance value in the pair of first electrode portions S11 and in the pair of second electrode portions S21. This case can facilitate manufacture of the wiring board 101C because the opening parts can be formed simultaneously.

A dimension L1y of the first opening part O1 in the y direction may be less than each of a dimension L2y of the second opening part O2 in the y direction and a dimension L3y of the third opening part O3. Thus, the dimension L1y of the first opening part O1 in the y direction can be set to a distance according to the size of the electric circuit element, and the possibility of decrease in impedance value in the vicinity of the electric circuit element can be effectively reduced without increasing the size of the wiring board 101C.

### Fourth Embodiment

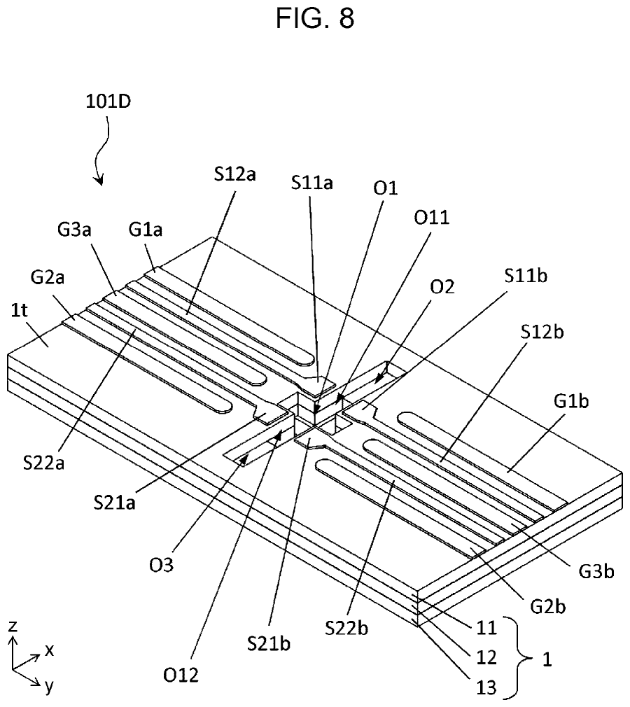

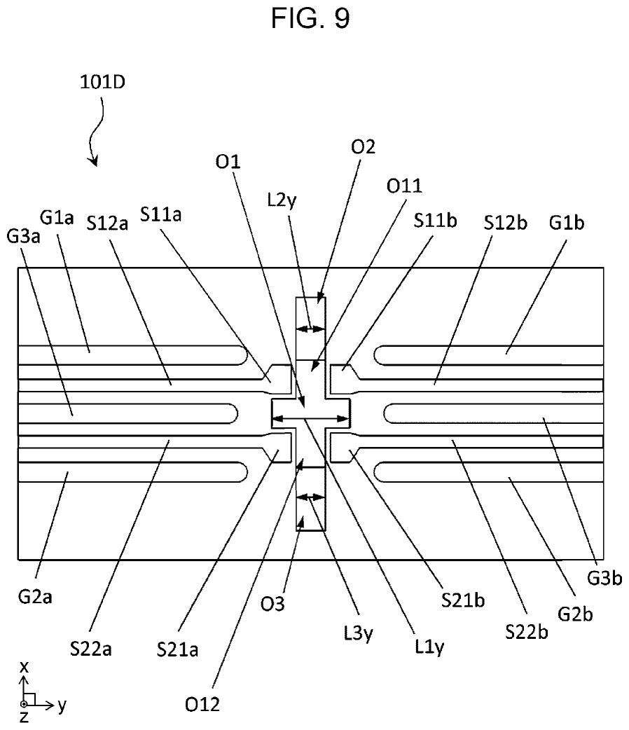

A wiring board 101D according to the fourth embodiment will be described with reference to FIGS. 8 and 9.

An insulator 1 further includes a second opening part O2 and a third opening part O3.

In the fourth embodiment, a dimension L1y of a first opening part O1 in the y direction may be greater than each of a dimension L2y of the second opening part O2 in the y direction and a dimension L3y of the third opening part O3 in the y direction. This configuration can reduce the possibility of decrease in strength of the insulator 1, by making the dimension L2y of the second opening part O2 in the y direction and/or the dimension L3y of the third opening part O3 in the y direction less than the dimension L1y of the first opening part O1 in the y direction, while effectively adjusting an impedance value with the opening parts.

Note that the dimension L2y of the second opening part O2 in the y direction may be the same as or different from the dimension L3y of the third opening part O3 in the y direction.

### Fifth Embodiment

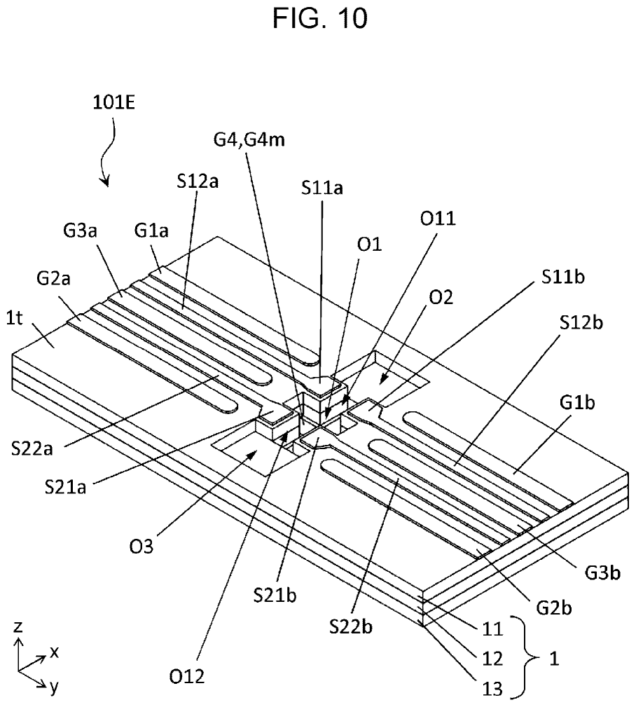

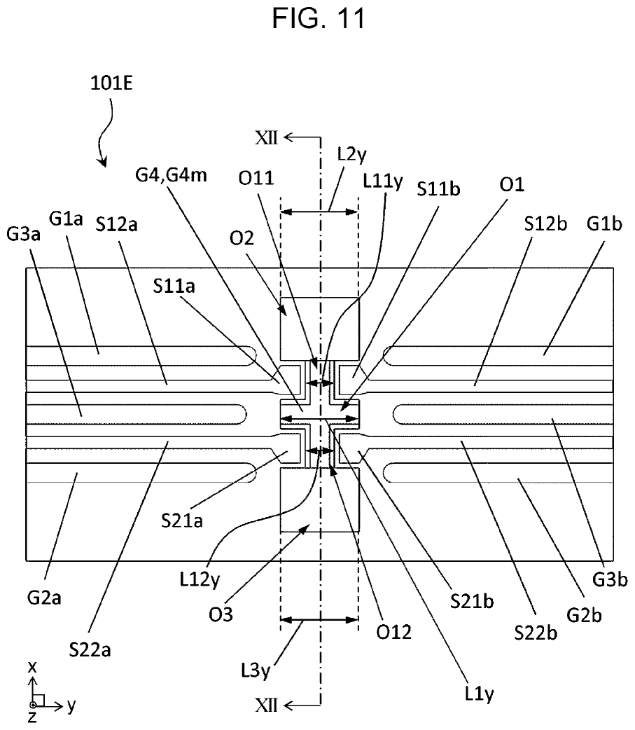

A wiring board 101E according to the fifth embodiment will be described with reference to FIGS. 10 to 13.

In the fifth embodiment, a first opening part O1 may have a dimension L1y that is a maximum dimension in the y direction, between a first signal conductor S1 and a second signal conductor S2. In this case, a dimension L11y of a first connection portion O1 in they direction and a dimension L12y of a second connection portion O12 in the y direction may each be less than the dimension L1y of the first opening part O1 in the y direction. A dimension L2y of a second opening part O2 in the y direction and/or a dimension L3y of a third opening part O3 in the y direction may be not less than the dimension L1y of the first opening part O1 in the y direction. In other words, at least a portion of a pair of first electrode portions S11 may be surrounded by the first opening part O1 including the first connection portion O11 and by the second opening part O2. At least a portion of a pair of second electrode portions S21 may be surrounded by the first opening part O1 including the second connection portion O12 and by the third opening part O3. Thus, in the vicinity of the electrode portion, the volume of an insulator 1 can be further reduced. Thus, the possibility of decrease in impedance value can be reduced more effectively in the first signal conductor S1 and the second signal conductor S2.

A depth D1 of the first opening part O1 may be greater than at least one of a depth D2 of the second opening part O2 and a depth D3 of the third opening part O3. This configuration can reduce the possibility of decrease in strength of the insulator 1 in the second opening part O2 and/or the third opening part O3 while further reducing the volume of the insulator 1 in the vicinity of the electrode portion where an impedance value may decrease. Such “depths” here can refer to maximum dimensions from a first upper surface It to a bottom surface of the first opening part O1, to a bottom surface of the second opening part O2, and to a bottom surface of the third opening part O3 in the z direction. In a sectional view perpendicular to the first upper surface It, the bottom surface of the opening part may have a curved-line shape protruding in the negative direction of the z axis.

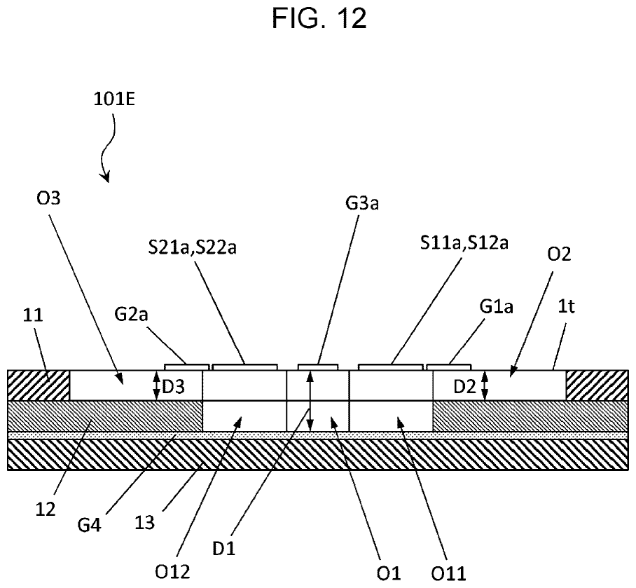

As FIG. 12 illustrates, in the fifth embodiment, the first opening part O1 extends to a first insulating layer 11 and to a second insulating layer 12, whereas the second opening part O2 and the third opening part O3 are positioned only in the first insulating layer 11. Note that the second opening part O2 and the third opening part O3 do not necessarily extend through the first insulating layer 11. The first opening part O1 does not also necessarily extend through the first insulating layer 11 and the second insulating layer 12.

In another embodiment, the depth D1 of the first opening part O1 may be less than at least one of the depth D2 of the second opening part O2 and the depth D3 of the third opening part O3. For example, in the wiring board 101E, an impedance value between adjacent signal conductors of the signal conductor part S0, when positioned close to each other, may decrease. Thus, the above-described configuration can reduce the possibility of decrease in impedance value in adjacent signal conductors of the signal conductor part S0.

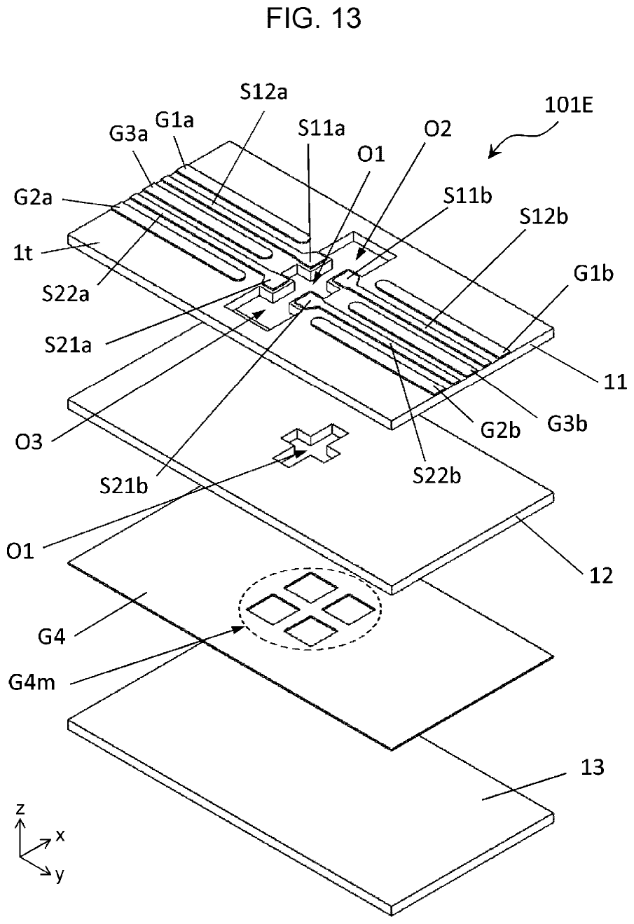

In an embodiment, an inner-layer ground conductor G4 may be positioned between the second insulating layer 12 and a third insulating layer 13. As FIG. 13 illustrates, the inner-layer ground conductor G4 may include a grid portion G4m. The grid portion G4m is a portion, of the inner-layer ground conductor G4, including through holes and in which the conductor is reticulate. The grid portion G4m may be partially exposed at a bottom surface of the first opening part O1. In plan view, at least a portion of the electrode portion may be at a position, in the grid portion G4m, at which the electrode portion overlaps a through-hole. This configuration can reduce the possibility of decrease in impedance value in the electrode portion while stabilizing the ground potential of the wiring board 101E.

### Sixth Embodiment

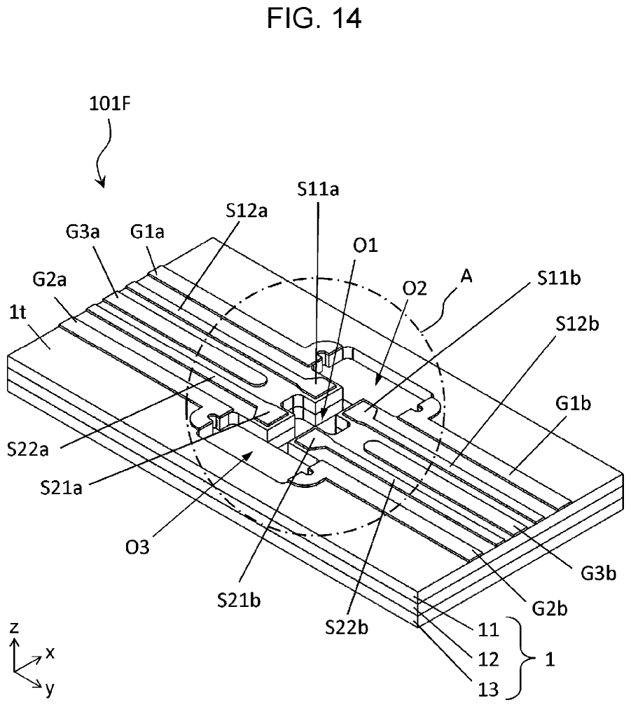

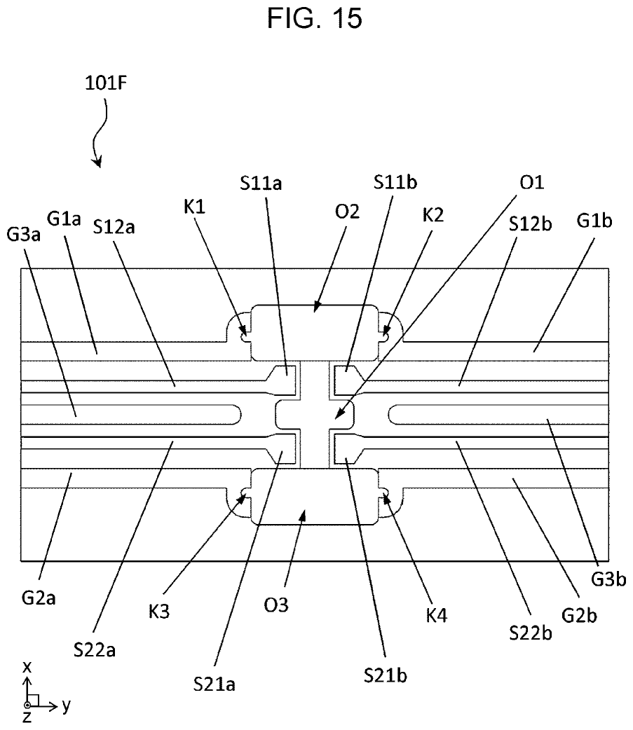

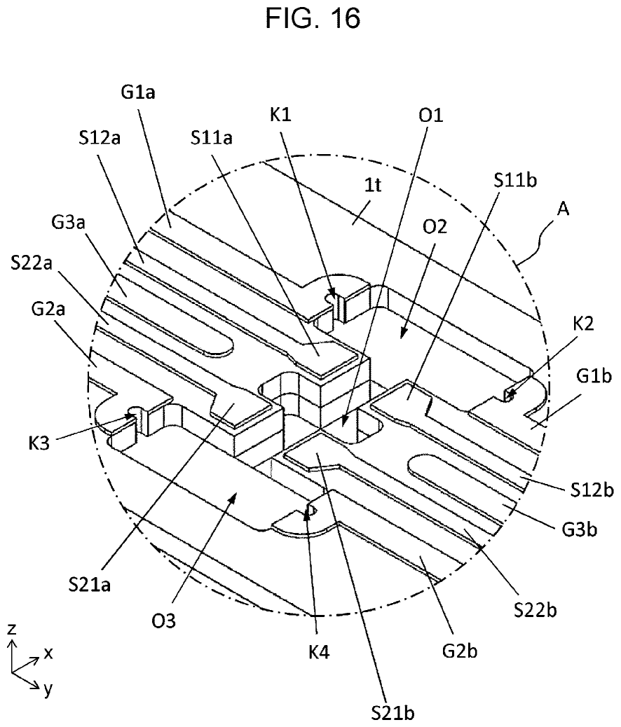

A wiring board 101F according to the sixth embodiment will be described with reference to FIGS. 14 to 16.

In plan view, a second opening part O2 may be in contact with a first ground line G1a and a second ground line G1b. In plan view, a third opening part O3 may be in contact with a third ground line G2a and a fourth ground line G2b. This configuration can further facilitate the impedance adjustment in the vicinity of an electrode portion.

The second opening part O2 may include a first cutout portion K1 at a position at which the second opening part O2 is in contact with the first ground line G1a and a second cutout portion K2 at a position at which the second opening part O2 is in contact with the second ground line G1b.

The third opening part O3 may include a third cutout portion K3 at a position at which the third opening part O3 is in contact with the third ground line G2a and a fourth cutout portion K4 at a position at which the third opening part O3 is in contact with the fourth ground line G2b.

A conductor may be positioned on an inner surface of each of the first cutout portion K1, the second cutout portion K2, the third cutout portion K3, and the fourth cutout portion K4. That is, the first cutout portion K1, the second cutout portion K2, the third cutout portion K3, and the fourth cutout portion K4 may each be a so-called castellation. Thus, the wiring board 101F can have strengthened ground potential.

### Simulation Results

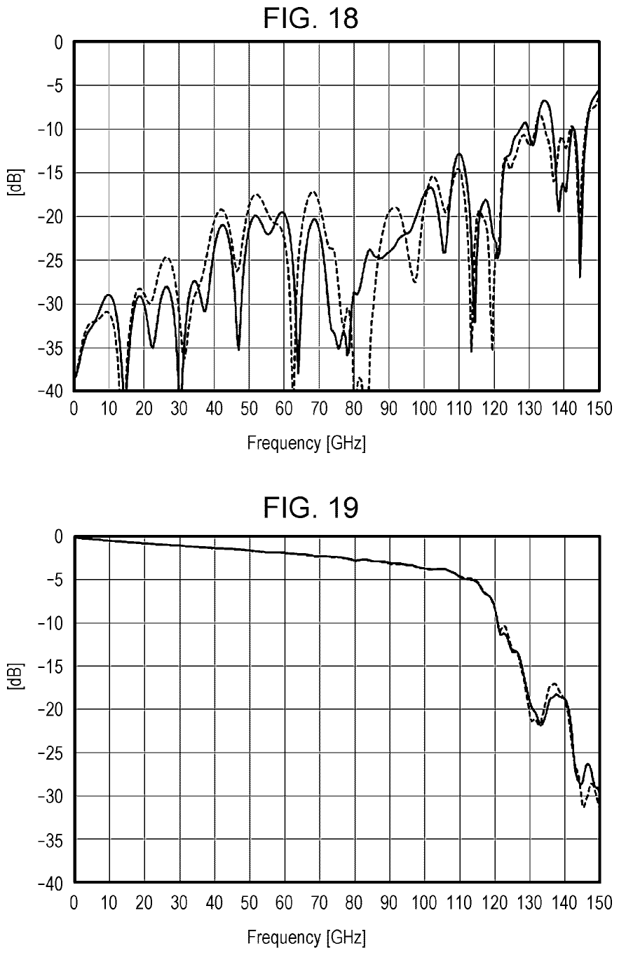

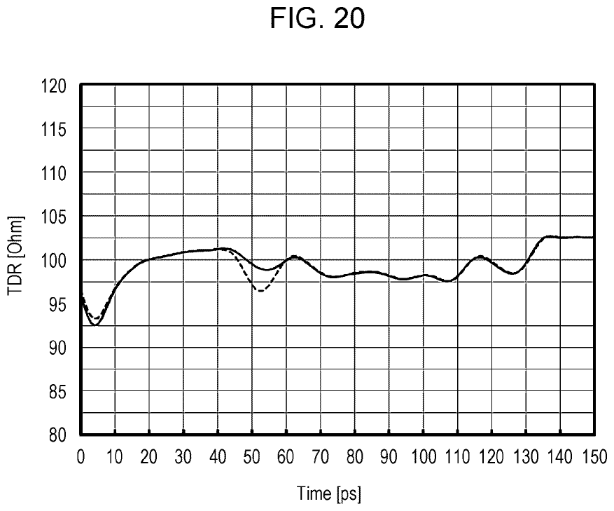

FIG. 18 is a graph illustrating reflection characteristics of the wiring boards 101 according to the fourth embodiment and the fifth embodiment. The horizontal axis represents frequency (GHz) of an input signal, and the vertical axis represents reflection characteristics (dB). The graph illustrating reflection characteristics means that the smaller a value of reflection characteristics (dB), the smaller a signal reflection. The broken line represents the characteristics of the fourth embodiment, and the solid line represents the characteristics of the fifth embodiment (the same applies to FIGS. 19 and 20, which will be described later). The graph shows that the fourth embodiment and the fifth embodiment both achieve good reflection characteristics in the range from 0 GHz to 110 GHz. The graph shows that the fifth embodiment achieves better characteristics than the fourth embodiment.

FIG. 19 is a graph illustrating bandpass characteristics of the wiring boards 101 according to the fourth embodiment and the fifth embodiment. The horizontal axis represents frequency (GHz) of an input signal, and the vertical axis represents bandpass characteristics (dB). The graph illustrating bandpass characteristics means that the larger a value of bandpass characteristics (dB), the smaller a signal loss. The graph shows that the fifth embodiment and the fourth embodiment both achieve good bandpass characteristics in the range from 0 GHz to 110 GHz.

FIG. 20 is a graph illustrating TDR of the wiring boards 101 according to the fourth embodiment and the fifth embodiment. The horizontal axis represents time (ps), and the vertical axis represents TDR (Ohm). The graph shows that the fourth embodiment and the fifth embodiment both achieve good characteristics. The graph shows that the fifth embodiment achieves better characteristics than the fourth embodiment.

### Configuration of Electronic-Component-Mounting Package

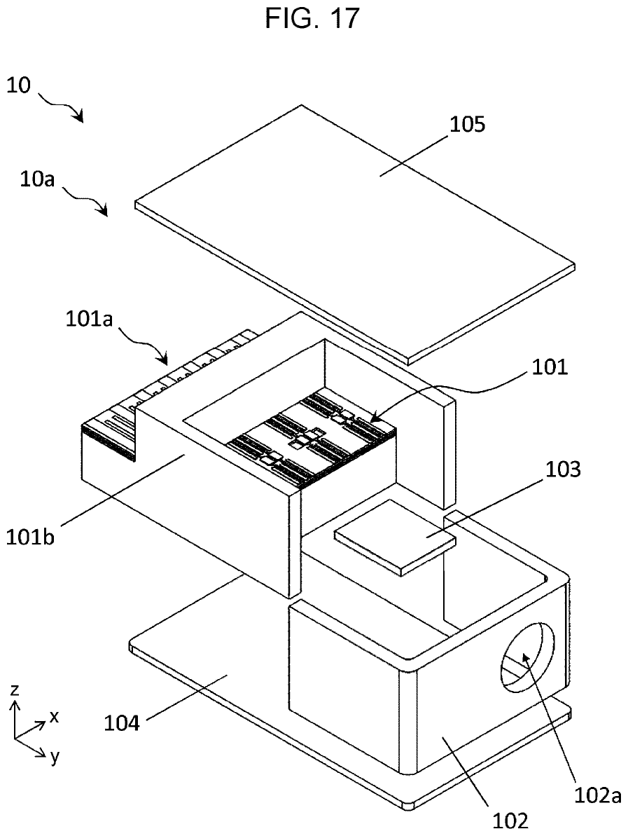

As FIG. 17 illustrates, an electronic-component-mounting package 10a according to an embodiment includes the wiring board 101, a base body 104, and a frame body 102. The frame body 102 is positioned on the base body 104. The wiring board 101 is fixed to the frame body 102.

In an embodiment, the wiring board 101 may include an input/output terminal portion 101a and a frame-shaped portion 101b. The wiring board 101 may be connected to an external connection member by an adhesive.

The input/output terminal portion 101a may be positioned outside the electronic-component-mounting package 10a. In this case, the input/output terminal portion 101a may be electrically connected to the signal conductor part S0 and the ground conductor part G0 of the wiring board 101 and may bring the inside and the outside of the electronic-component-mounting package 10a into conduction. The pair of first electrode portions S11 and the pair of second electrode portions S12 described above may be positioned inside the electronic-component-mounting package 10a.

The external connection member may be connected to the input/output terminal portion 101a.

For example, such an “external connection member” here may be FPC (flexible printed circuits) or a PCB (printed circuit board) on which an electric circuit is formed or may be a metal member, that is, for example, a lead terminal and/or a bonding wire. Such connection of the external connection member to the input/output terminal portion 101a enables an electronic component 103 mounted on the electronic-component-mounting package 10a to operate.

The frame-shaped portion 101b may be partially bonded to the frame body 102, which will be described later. That is, the inside of the electronic-component-mounting package 10a is surrounded by the frame-shaped portion 101b and the frame body 102.

The wiring board 101 may be bonded to an upper surface of the base body 104. For example, the base body 104 has a rectangular shape in plan view and has a size of from 10 mm×10 mm to 50 mm×50 mm and a thickness of from 0.5 mm to 20 mm. The material of the base body 104 is, for example, a metal material such as copper, iron, tungsten, molybdenum, nickel, or cobalt, or an alloy containing such an above-described metal material. In this case, the base body 104 may be a single metal plate or a multilayer body in which multiple metal plates are stacked. When the material of the base body 104 is such a metal material described above, a plating layer of, for example, nickel or gold may be formed on a surface of the base body 104 by an electroplating method or an electroless plating method, for the purpose of reducing oxidized corrosion. The material of the base body 104 may be an insulating material and may be, for example, a ceramic material such as sintered aluminum oxide, sintered mullite, sintered silicon carbide, sintered aluminum nitride, sintered silicon nitride, or a glass ceramic.

The base body 104 may be a PCB on which an electric circuit is printed. In this case, the wiring board 101 may be bonded to the base body 104 by a BGA.

The frame body 102 is positioned on the upper surface of the base body 104 and protects the electronic component 103 positioned inside the frame body 102 in plan view. That is, the frame body 102 surrounds at least a portion of a periphery of the electronic component 103 in plan view. The frame body 102 does not necessarily surround an entire outer edge of the upper surface of the base body 104. The frame body 102 is positioned along the outer edge of the upper surface of the base body 104 in an embodiment but may be positioned on the inner side relative to the outer edge of the upper surface of the base body 104.

The frame body 102 may have a rectangular shape in plan view. In this case, the wiring board 101 may be bonded to a lower surface of the frame body 102. When the wiring board 101 is bonded to the upper surface of the base body 104, the wiring board 101 may be interposed between the frame body 102 and the base body 104.

The material of the frame body 102 may be, for example, a metal material such as copper, iron, tungsten, molybdenum, nickel, or cobalt, or an alloy containing such an above-described metal material. The material of the frame body 102 may be an insulating material and may be, for example, a ceramic material such as sintered aluminum oxide, sintered mullite, sintered silicon carbide, sintered aluminum nitride, sintered silicon nitride, or a glass ceramic.

The frame body 102 can be bonded to the base body 104 by using, for example, a brazing material. Note that, for example, the material of the brazing material is silver, copper, gold, aluminum, or magnesium and may contain an additive such as nickel, cadmium, or phosphorus.

The frame body 102 may include a through-hole portion 102a. A fixation member including a light-transmissive window member may be bonded to the through-hole portion 102a. An optical fiber may be inserted in and fixed to the fixation member.

### Configuration of Electronic Module

An electronic module 10 according to an embodiment includes the electronic-component-mounting package 10a, the electronic component 103, and a lid body 105. The electronic component 103 is positioned on the base body 104 and electrically connected to the wiring board 101. The lid body 105 is positioned on the frame body 102 and covers the inside of the electronic-component-mounting package 10a.

In the electronic module 10, the wiring board 101 may be a wiring structure 100 that is connected to the external connection member by using an adhesive.

The electronic component 103 may perform, for example, signal processing such as converting an optical signal into an electrical signal or converting an electrical signal into an optical signal. The electronic component 103 is positioned on the upper surface of the base body 104 and accommodated in the electronic-component-mounting package 10a.

The electronic component 103 may perform, for example, signal processing such as converting a radio signal or an optical signal into an electrical signal or converting an electrical signal into a radio signal or an optical signal. The electronic component 103 may be bonded directly to the base body 104. A base containing a ceramic material and/or a metal material may be positioned between the electronic component 103 and the base body 104. That is, the electronic component 103 may be bonded indirectly to the base body 104.

Examples of the electronic component 103 include an optical semiconductor element such as an LD (laser diode) or a PD (photo diode), a semiconductor integrated circuit element such as an FET (field effect transistor), and a sensor element such as an optical sensor. The electronic component 103 can be formed by using, for example, a semiconductor material such as gallium arsenide or gallium nitride.

The lid body 105 is positioned on the frame body 102 and, while covering the inside of the electronic-component-mounting package 10a, protects the electronic component 103 together with the frame body 102. The lid body 105 may have a quadrilateral shape in plan view. The lid body 105 may have a size of from 10 mm×10 mm to 50 mm×50 mm and a thickness of from 0.5 mm to 2 mm. The material of the lid body 105 is, for example, a metal material such as iron, copper, nickel, chromium, cobalt, molybdenum, or tungsten, or an alloy into which multiple ones of the above-described metal materials are combined. An ingot of such a metal material is subjected to a metalworking method such as a rolling method or a punching method, and a metal member constituting the lid body 105 can thus be fabricated.

The electronic module 10 may further include a seal ring positioned between the lid body 105 and the frame body 102. The seal ring has a function of bonding the lid body 105 and the frame body 102 to each other. The seal ring is positioned on the frame body 102 and surrounds the electronic component 103 in plan view. For example, the material of the seal ring is a metal material such as iron, copper, silver, nickel, chromium, cobalt, molybdenum, or tungsten, or an alloy into which multiple ones of the above-described metal materials are combined. Note that, when no seal ring is provided on the frame body 102, for example, the lid body 105 may be bonded on the frame body 102 by using an adhesive such as solder, a brazing material, glass, or a resin adhesive.

Note that various combinations of features in each embodiment and each alternative embodiment are not limited to the examples of the embodiments described above. Combinations among the embodiments and among the alternative embodiments are possible.

In an embodiment (1), a wiring board includes an insulator, a ground conductor part, and a signal conductor part. The insulator includes a first upper surface. The first upper surface includes a first region extending in a first direction. The ground conductor part is positioned on the first upper surface and extends in a second direction crossing the first direction. The signal conductor part is positioned on the first upper surface and extends in the second direction. The insulator includes a first opening part including at least a portion positioned in the first region. The ground conductor part includes a first ground conductor, and a second ground conductor spaced from the first ground conductor. The signal conductor part includes a first signal conductor and a second signal conductor. The first signal conductor is positioned between the first ground conductor and the second ground conductor. The second signal conductor is spaced from the first signal conductor and positioned between the first ground conductor and the second ground conductor. The first ground conductor includes a first ground line and a second ground line. The second ground line is opposite to the first ground line across the first region in the second direction. The second ground conductor includes a third ground line and a fourth ground line. The fourth ground line is opposite to the third ground line across the first region in the second direction. The first signal conductor includes a pair of first electrode portions, a first line portion, and a second line portion. The pair of first electrode portions are opposite to each other across the first region in the second direction. The first line portion is connected to one of the pair of first electrode portions and extends away from the first region. The second line portion is connected to the other of the pair of first electrode portions and extends away from the first region. The second signal conductor includes a pair of second electrode portions, a third line portion, and a fourth line portion. The pair of second electrode portions are opposite to each other across the first region in the second direction. The third line portion is connected to one of the pair of second electrode portions and extends away from the first region. The fourth line portion is connected to the other of the pair of second electrode portions and extends away from the first region. The first ground conductor, the first signal conductor, the second signal conductor, and the second ground conductor are arranged in this order in the first direction in plan view. The first opening part is positioned in a first portion, of the first region, positioned between the first signal conductor and the second signal conductor in the first direction.

(2) In the wiring board according to the item (1), a distance between the pair of first electrode portions in the second direction and a distance between the pair of second electrode portions in the second direction are each less than at least one of a distance between the first ground line and the second ground line in the second direction and a distance between the third ground line and the fourth ground line in the second direction.

(3) In the wiring board according to the item (1) or (2), a dimension of the first opening part in the second direction is greater than at least one of a distance between the pair of first electrode portions in the second direction and a distance between the pair of second electrode portions in the second direction.

(4) In the wiring board according to any one of the items (1) to (3), a dimension of the first opening part in the second direction is less than at least one of a distance between the first ground line and the second ground line in the second direction and a distance between the third ground line and the fourth ground line in the second direction.

(5) In the wiring board according to any one of the items (1) to (4), the first opening part extends at least from a spot between the pair of first electrode portions to a spot between the pair of second electrode portions.

(6) In the wiring board according to the item (5), a dimension of the first opening part in the first direction is greater than a distance between the first ground conductor and the second ground conductor in the first direction.

(7) In the wiring board according to any one of the items (1) to (6), the insulator further includes a second opening part and a third opening part. The second opening part includes at least a portion positioned in the first region. The third opening part includes at least a portion positioned in the first region. The second opening part is positioned between the first ground line and the second ground line in the second direction and is spaced from the first signal conductor in the first direction. The third opening part is positioned between the third ground line and the fourth ground line in the second direction and is spaced from the second signal conductor in the first direction.

(8) In the wiring board according to the item (7), the first opening part includes a first connection portion and a second connection portion. The first connection portion is connected to the second opening part. The first connection portion is positioned between the pair of first electrode portions in the second direction. The second connection portion is connected to the third opening part. The second connection portion is positioned between the pair of second electrode portions in the second direction.

(9) In the wiring board according to the item (7) or (8), a dimension of the first opening part in the second direction is less than each of a dimension of the second opening part in the second direction and a dimension of the third opening part.

(10) In the wiring board according to any one of the items (7) to (9), a depth of the first opening part is greater than at least one of a depth of the second opening part and a depth of the third opening part.

(11) In the wiring board according to any one of the items (7) to (10), the second opening part is in contact with the first ground line and the second ground line in plan view. The third opening part is in contact with the third ground line and the fourth ground line in plan view.

(12) In the wiring board according to any one of the items (1) to (11), the ground conductor part further includes a third ground conductor positioned between the first signal conductor and the second signal conductor. The third ground conductor includes a fifth ground line and a sixth ground line. The sixth ground line is opposite to the fifth ground line across the first region in the second direction.

(13) In the wiring board according to the item (12), a distance between the fifth ground line and the sixth ground line in the second direction is greater than at least one of a distance between the first ground line and the second ground line in the second direction and a distance between the third ground line and the fourth ground line in the second direction.

(14) In an embodiment, an electronic-component-mounting package includes the wiring board according to any one of the items (1) to (13), a substrate, and a frame body. The frame body is positioned on the substrate. The wiring board is fixed to the frame body.

(15) In an embodiment, an electronic module includes the electronic-component-mounting package according to the item (14), an electronic component, and a lid body. The electronic component is accommodated in the electronic-component-mounting package and electrically connected to the wiring board. The lid body is bonded on the frame body and covers an inside of the electronic-component-mounting package.

### INDUSTRIAL APPLICABILITY

The present disclosure can be used as a wiring board, an electronic-component-mounting package using a wiring board, and an electronic module.

### REFERENCE SIGNS

REFERENCE SIGNS

| | |
|---|---|
| 1 | insulator |
| 1t | first upper surface |
| 1s | first region |
| 1r | first portion |
| 11 | first insulating layer |
| 12 | second insulating layer |
| 13 | third insulating layer |
| O1 | first opening part |
| O11 | first connection portion |
| O12 | second connection portion |
| O2 | second opening part |
| O3 | third opening part |
| K1 | first cutout portion |
| K2 | second cutout portion |
| K3 | third cutout portion |
| K4 | fourth cutout portion |
| T1 | first imaginary line |
| T2 | second imaginary line |
| D1 | depth of first opening part |
| D2 | depth of second opening part |
| D3 | depth of third opening part |
| L1x | dimension of first opening part in the x direction |
| L1y | dimension of first opening part in the y direction |
| L2y | dimension of second opening part in the y direction |
| L3y | dimension of third opening part in the y direction |
| L11y | dimension of first connection portion O11 in the |
| | y direction |
| L12y | dimension of second connection portion O12 in |
| | the y direction |
| G0 | ground conductor part |
| G1 | first ground conductor |
| G1a | first ground line |
| G1b | second ground line |
| G2 | second ground conductor |
| G2a | third ground line |
| G2b | fourth ground line |
| G3 | third ground conductor |
| G3a | fifth ground line |
| G3b | sixth ground line |
| G4 | inner-layer ground conductor |
| G4m | grid portion |
| Lg1 | distance between first ground line and second |
| | ground line in the y direction |
| Lg2 | distance between third ground line and fourth |
| | ground line in the y direction |
| Lg3 | distance between fifth ground line and sixth |
| | ground line in the y direction |
| Lg12 | distance between first ground conductor and |
| | second ground conductor in the x direction |
| S0 | signal conductor part |
| S1 | first signal conductor |
| S11 | pair of first electrode portions |
| S12a | first line portion |
| S12b | second line portion |
| S2 | second signal conductor |
| S21 | pair of second electrode portions |
| S22a | third line portion |
| S22b | fourth line portion |
| Ls1 | distance between pair of first electrode portions |
| Ls2 | distance between pair of second electrode portions |
| 31 | first capacitor |
| 32 | second capacitor |
| 10 | electronic module |
| 10a | electronic-component-mounting package |
| 101A to 101F | wiring board |
| 101a | input/output terminal portion |
| 101b | frame-shaped portion |
| 102 | frame body |
| 102a | through-hole portion |
| 103 | electronic component |
| 104 | base body |
| 105 | lid body |

1. A wiring board comprising:
an insulator comprising a first upper surface, the first upper surface comprising a first region extending in a first direction;
a ground conductor part positioned on the first upper surface and extending in a second direction crossing the first direction; and
a signal conductor part positioned on the first upper surface and extending in the second direction, wherein
the insulator comprises a first opening part comprising at least a portion positioned in the first region,
the ground conductor part comprises:
a first ground conductor; and
a second ground conductor spaced from the first ground conductor,
the signal conductor part comprises:
a first signal conductor positioned between the first ground conductor and the second ground conductor; and
a second signal conductor spaced from the first signal conductor and positioned between the first ground conductor and the second ground conductor,
the first ground conductor comprises:
a first ground line; and
a second ground line opposite to the first ground line across the first region in the second direction,
the second ground conductor comprises:
a third ground line; and
a fourth ground line opposite to the third ground line across the first region in the second direction,
the first signal conductor comprises:
a pair of first electrode portions opposite to each other across the first region in the second direction;
a first line portion connected to one of the pair of first electrode portions and extending away from the first region; and
a second line portion connected to an other of the pair of first electrode portions and extending away from the first region,
the second signal conductor comprises:
a pair of second electrode portions opposite to each other across the first region in the second direction;
a third line portion connected to one of the pair of second electrode portions and extending away from the first region; and
a fourth line portion connected to an other of the pair of second electrode portions and extending away from the first region,
the first ground conductor, the first signal conductor, the second signal conductor, and the second ground conductor are arranged in this order in the first direction in plan view, and
the first opening part is positioned in a first portion, of the first region, positioned between the first signal conductor and the second signal conductor in the first direction.

2. The wiring board according to claim 1, wherein
a distance between the pair of first electrode portions in the second direction and a distance between the pair of second electrode portions in the second direction are each less than at least one of a distance between the first ground line and the second ground line in the second direction and a distance between the third ground line and the fourth ground line in the second direction.

3. The wiring board according to claim 1, wherein
a dimension of the first opening part in the second direction is greater than at least one of a distance between the pair of first electrode portions in the second direction and a distance between the pair of second electrode portions in the second direction.

4. The wiring board according to claim 1, wherein
a dimension of the first opening part in the second direction is less than at least one of a distance between the first ground line and the second ground line in the second direction and a distance between the third ground line and the fourth ground line in the second direction.

5. The wiring board according to claim 1, wherein
the first opening part extends at least from a spot between the pair of first electrode portions to a spot between the pair of second electrode portions.

6. The wiring board according to claim 5, wherein
a dimension of the first opening part in the first direction is greater than a distance between the first ground conductor and the second ground conductor in the first direction.

7. The wiring board according to claim 1, wherein
the insulator further comprises:
a second opening part comprising at least a portion positioned in the first region; and
a third opening part comprising at least a portion positioned in the first region,
the second opening part is positioned between the first ground line and the second ground line in the second direction and is spaced from the first signal conductor in the first direction, and
the third opening part is positioned between the third ground line and the fourth ground line in the second direction and is spaced from the second signal conductor in the first direction.

8. The wiring board according to claim 7, wherein
the first opening part comprises:
a first connection portion connected to the second opening part; and
a second connection portion connected to the third opening part, the first connection portion is positioned between the pair of first electrode portions in the second direction, and
the second connection portion is positioned between the pair of second electrode portions in the second direction.

9. The wiring board according to claim 7, wherein
a dimension of the first opening part in the second direction is less than each of a dimension of the second opening part in the second direction and a dimension of the third opening part in the second direction.

10. The wiring board according to claim 7, wherein
a depth of the first opening part is greater than at least one of a depth of the second opening part and a depth of the third opening part.

11. The wiring board according to claim 7, wherein
the second opening part is in contact with the first ground line and the second ground line in plan view, and
the third opening part is in contact with the third ground line and the fourth ground line in plan view.

12. The wiring board according to claim 1, wherein
the ground conductor part further comprises a third ground conductor positioned between the first signal conductor and the second signal conductor, and
the third ground conductor comprises:
a fifth ground line; and
a sixth ground line opposite to the fifth ground line across the first region in the second direction.

13. The wiring board according to claim 12, wherein
a distance between the fifth ground line and the sixth ground line in the second direction is greater than at least one of a distance between the first ground line and the second ground line in the second direction and a distance between the third ground line and the fourth ground line in the second direction.

14. An electronic-component-mounting package comprising:
a substrate;
a frame body positioned on the substrate; and
the wiring board according to claim 1, the wiring board being fixed to the frame body.

15. An electronic module comprising:
the electronic-component-mounting package according to claim 14;
an electronic component accommodated in the electronic-component-mounting package and electrically connected to the wiring board; and
a lid body bonded on the frame body and covering an inside of the electronic-component-mounting package.
